(19) United States
(12) Patent Application Publication
(10) Pub. No.: US 2025/0015037 A1
(43) Pub. Date: Jan. 9, 2025

(54) BALL-BOND ARRANGEMENT

(71) Applicant: Heraeus Materials Singapore Pte. Ltd., Singapore (SG)

(72) Inventors: Yee Weon LIM, Singapore (SG); Murali SARANGAPANI, Singapore (SG); Mariyappan DHAYALAN, Singapore (SG); Shern Jiang CHING, Singapore (SG); Mei Hoe CHONG, Singapore (SG); Miew Wan LO, Singapore (SG); Chee Chow TAN, Singapore (SG); Yean Mee PUN, Singapore (SG); Sungsig KANG, Singapore (SG)

(21) Appl. No.: 18/711,454

(22) PCT Filed: Nov. 23, 2021
(86) PCT No.: PCT/SG2021/050719

§ 371 Date: May 17, 2024

(51) Int. Cl. H01L 23/00

(52) U.S. Cl. CPC H01L 24/48; H01L 24/05; H01L 24/43; H01L 24/45; H01L 2224/05624; H01L 2224/05639; H01L 2224/05644; H01L 2224/05647; H01L 2224/05655; H01L 2224/05664; H01L 2224/43848; H01L 2224/45005; H01L 2224/45139; H01L 2224/45164; H01L 2224/45572; H01L 2224/45613; H01L 2224/4562; H01L 2224/45644; H01L 2224/45655; H01L 2224/45664; H01L 2224/48227; H01L 2224/4845; H01L 2924/30101

(57) ABSTRACT

A ball-bond arrangement comprising a bond pad of a semiconductor device and a wire ball-bonded to the bond pad, wherein the wire extending from the bonded ball has a diameter of 15 to 50 μm, and comprises a silver-based wire core with a surface, the wire core having a coating layer superimposed on its surface, wherein the coating layer is a double-layer comprised of a 1 to 40 nm thick inner layer of palladium or nickel and an adjacent 20 to 500 nm thick outer layer of gold, and wherein the surface of the bonded ball has a gold coverage of 70 to 100%.

The invention relates to a ball-bond arrangement comprising a bond pad of a semiconductor device and a wire ball-bonded to the bond pad.

Wire ball-bonding is well-known in the art. The first step of wire ball-bonding is FAB (free air ball) formation at the tip of a round bonding wire. FAB formation is then followed by the actual ball-bonding procedure. Ball bonding of a FAB to a bond pad of a semiconductor device results in formation of a so-called ball-bond arrangement, or, to be more precise, a ball-bond arrangement comprising a bond pad of a semiconductor device and a wire ball-bonded to the bond pad. The ball-bonded wire comprises the bonded ball which becomes narrow towards its top, where it has a neck from where the wire extends at its original diameter. During the ball-bonding procedure the FAB has been deformed to a bonded ball having a closed bell-like shape, wherein the bottom of the closed bell has an interface with the bond pad and wherein the wire extends from the top of the bell; i.e. wherein the wire extends from said neck.

The term “bond pad” is used herein. It means bond pads, in particular bond pads of semiconductor devices. Bond pads may consist of a metal M or of an alloy of >90 wt.-% (% by weight) of a metal M or they may consist of a metal other than the metal M with an outer metal M (alloy) top layer. Such top layer may have a thickness of, for example, 0.5 to 1 μm. The metal M may be aluminum, gold, silver, copper, palladium, or nickel, in particular aluminum or nickel. Bond pads may have an overall thickness of, for example, 0.2 to 4 μm.

KR101687597B1 discloses a silver-based bonding wire having an external gold layer. When a FAB in air atmosphere is formed at the tip of the gold-coated silver-based bonding wire, the gold content on the outer surface of the FAB is 5 to 35 wt.-%.

The applicant has found that a ball-bond arrangement of a silver-based bonding wire having an outer gold coating layer and being ball-bonded to a bond pad of a semiconductor device exhibits a remarkably high gold coverage of 70 to 100% of the surface of the bonded ball, when the bonding wire has a nickel or a palladium inter-layer between the silver-based surface of the wire core and the outer gold coating layer and when FAB formation is performed at a BSR (ball size ratio; FAB diameter divided by the wire diameter) in the range of 1.5 to 2.2. It is believed that a high gold coverage of 70 to 100% of the surface of the bonded ball forms the basis of considerable galvanic corrosion prevention of the ball-bond arrangement, or in other words, prevention of galvanic corrosion at the junction or at the ball-bond interface of the ball-bond arrangement. The beneficial result of prevention of galvanic corrosion is the avoidance of bond lift-off of the ball-bond arrangement. Galvanic corrosion behavior of a ball-bond arrangement can be tested carrying out a so-called bHAST test (see “Test method A” as described below).

Hence, the invention relates to a ball-bond arrangement. The ball-bond arrangement of the invention comprises a bond pad of a semiconductor device and a wire ball-bonded to the bond pad,
wherein the wire extending from the bonded ball has a diameter of 15 to 50 μm, and comprises a silver-based wire core with a surface, the wire core having a coating layer superimposed on its surface,
wherein the coating layer is a double-layer comprised of a 1 to 40 nm, preferably 1.5 to 15 nm thick inner layer of palladium or preferably nickel and an adjacent 20 to 500 nm, preferably 30 to 350 nm thick outer layer of gold, and
wherein the surface of the bonded ball has a gold coverage of 70 to 100%.

The term “surface of the bonded ball” is used herein. It shall mean the entire surface of the bonded ball, i.e. the visible part of the surface plus the invisible part (bonded part, bottom part) of the surface of the bonded ball or, in other words, its visible part plus its bond interface with the bond pad. It is self-explanatory that the visible part of the surface does not include the surface of the wire extending from the neck of the bonded ball.

The term “gold coverage of the surface of the bonded ball” is used herein. It shall mean the percentage of the surface area of the bonded ball which is covered with gold. This percentage can be determined by performing a SEM EDX analysis (scanning electron microscope energy dispersive X-ray analysis) of a cross-sectioned ball-bond arrangement (see “Test method B” as described below). To this end, the bonded ball, i.e. the ball-bond arrangement, is epoxy potted, mechanically cross-sectioned to center of the ball-bond, and then ion-milled to attain scratch-free cross-sectional view. The ion-milled cross section is observed in SEM; with the support of energy dispersive X-ray attachment to SEM the ion-milled section is dot mapped for gold. It may be worked with a magnification in the range of, for example, 200 to 5000×, preferably 800 to 1300×; an electron beam excitation voltage in the range of, for example, 5 to 30 kV, preferably 5 to 10 KV, and a constant electrical current in the range of, for example, 30 to 950 pA, preferably 30 to 550 pA. The dot mapping for gold means looking for a spread of gold dots along the periphery of the bonded ball from said neck over said visible part and said invisible part of the bonded ball's surface on either side, i.e. it is looked for gold dots on the left-hand side, the right-hand side and the bottom of the bonded ball. If there are gold dots along the entire periphery, the gold coverage of the surface of the bonded ball is 100%. The evaluation of the percentage of the gold coverage is as follows:
− Poor: <70% of the bonded ball's periphery is covered by gold;
+ Good: 70 to 100% of the bonded ball's periphery is covered by gold.

A gold coverage of 70 to 100% correlates with a considerable resistance against galvanic corrosion of the ball-bond arrangement or, in other words, a considerable galvanic corrosion resistance at the junction or the ball-bond interface of the ball-bond arrangement and as a consequence thereof with good reliability of the ball-bond.

The 15 to 50 μm thick round wire comprises a wire core (hereinafter also called “core” for short) with a surface, the wire core having a coating layer superimposed on its surface, wherein the wire core itself is a silver-based wire core, wherein the coating layer is a double-layer comprised of a 1 to 40 nm, preferably 1.5 to 15 nm thick inner layer of palladium or preferably nickel and an adjacent 20 to 500 nm, preferably 30 to 350 nm thick outer layer of gold.

The wire core is silver-based; i.e. the wire core consists of a silver-based material in the form of doped silver, a silver alloy or a doped silver alloy.

The term “doped silver” used herein means a silver-based material consisting of (a1) silver in an amount in the range of from >99.49 to 99.997 wt.-%, (a2) at least one doping element other than silver in a total amount of from 30 to <5000 wt.-ppm (ppm by weight) and (a3) further components (components other than silver and the at least one doping element) in a total amount of from 0 to 100 wt.-ppm. In a preferred embodiment, the term “doped silver” used herein means doped silver consisting of (a1) silver in an amount in the range of from >99.49 to 99.997 wt.-%, (a2) at least one doping element selected from the group consisting of calcium, nickel, platinum, palladium, gold, copper, rhodium and ruthenium in a total amount of from 30 to <5000 wt.-ppm and (a3) further components (components other than silver, calcium, nickel, platinum, palladium, gold, copper, rhodium and ruthenium) in a total amount of from 0 to 100 wt.-ppm.

The term “silver alloy” used herein means a silver-based material consisting of (b1) silver in an amount in the range of from 89.99 to 99.5 wt.-%, preferably 97.99 to 99.5 wt.-%, (b2) at least one alloying element in a total amount in the range of from 0.5 to 10 wt.-%, preferably 0.5 to 2 wt.-% and (b3) further components (components other than silver and the at least one alloying element) in a total amount of from 0 to 100 wt.-ppm. In a preferred embodiment, the term “silver alloy” used herein means a silver alloy consisting of (b1) silver in an amount in the range of from 89.99 to 99.5 wt.-%, preferably 97.99 to 99.5 wt.-%, (b2) at least one alloying element selected from the group consisting of nickel, platinum, palladium, gold, copper, rhodium and ruthenium in a total amount in the range of from 0.5 to 10 wt.-%, preferably 0.5 to 2 wt.-% and (b3) further components (components other than silver, nickel, platinum, palladium, gold, copper, rhodium and ruthenium) in a total amount of from 0 to 100 wt.-ppm. Silver alloys comprising palladium as the only alloying element are most preferred, in particular those having a palladium content of 1 to 2 wt.-%, especially 1.5 wt.-%.

The term “doped silver alloy” used herein means a silver-based material consisting of (c1) silver in an amount in the range of from >89.49 to 99.497 wt.-%, preferably 97.49 to 99.497 wt.-%, (c2) at least one doping element in a total amount of from 30 to <5000 wt.-ppm, (c3) at least one alloying element in a total amount in the range of from 0.5 to 10 wt.-%, preferably 0.5 to 2 wt.-% and (c4) further components (components other than silver, the at least one doping element and the at least one alloying element) in a total amount of from 0 to 100 wt.-ppm, wherein the at least one doping element (c2) is other than the at least one alloying element (c3). In a preferred embodiment, the term “doped silver alloy” used herein means a doped silver alloy consisting of (c1) silver in an amount in the range of from >89.49 to 99.497 wt.-%, preferably 97.49 to 99.497 wt.-%, (c2) at least one doping element selected from the group consisting of calcium, nickel, platinum, palladium, gold, copper, rhodium and ruthenium in a total amount of from 30 to <5000 wt.-ppm, (c3) at least one alloying element selected from the group consisting of nickel, platinum, palladium, gold, copper, rhodium and ruthenium in a total amount in the range of from 0.5 to 10 wt.-%, preferably 0.5 to 2 wt.-% and (c4) further components (components other than silver, calcium, nickel, platinum, palladium, gold, copper, rhodium and ruthenium) in a total amount of from 0 to 100 wt.-ppm, wherein the at least one doping element (c2) is other than the at least one alloying element (c3).

This disclosure mentions “further components” and “doping elements”. The individual amount of any further component is less than 30 wt.-ppm. The individual amount of any doping element is at least 30 wt.-ppm. All amounts in wt.-% and wt.-ppm are based on the total weight of the core or its precursor item or elongated precursor item.

The core of the wire may comprise so-called further components in a total amount in the range of from 0 to 100 wt.-ppm, for example, 10 to 100 wt.-ppm. In the present context, the further components, often also referred as “inevitable impurities”, are minor amounts of chemical elements and/or compounds which originate from impurities present in the raw materials used or from the wire core manufacturing process. The low total amount of 0 to 100 wt.-ppm of the further components ensures a good reproducibility of the wire properties. Further components present in the core are usually not added separately. Each individual further component is comprised in an amount of less than 30 wt.-ppm, based on the total weight of the wire core.

The core of the wire is a homogeneous region of bulk material. Since any bulk material always has a surface region which might exhibit different properties to some extent, the properties of the core of the wire are understood as properties of the homogeneous region of bulk material. The surface of the bulk material region can differ in terms of morphology, composition (e.g. sulfur, chlorine and/or oxygen content) and other features. The surface is an interface region between the wire core and the coating layer superimposed on the wire core. Typically, the coating layer is completely superimposed on the wire core's surface. In the region of the wire between its core and the coating layer superimposed thereon a combination of materials of both, the core and the coating layer, can be present.

The coating layer superimposed on the surface of the wire core is a double-layer comprised of a 1 to 40 nm, preferably 1.5 to 15 nm thick inner layer of palladium or preferably nickel and an adjacent 20 to 500 nm, preferably 30 to 350 nm thick outer layer of gold. In this context the term “thick” or “coating layer thickness” means the size of the coating layer in perpendicular direction to the longitudinal axis of the core.

In a preferred embodiment, the outer gold layer comprises at least one member selected from the group consisting of antimony, bismuth, arsenic and tellurium in a total proportion in the range of from 10 to 300 wt.-ppm, preferably 10 to 120 wt.-ppm, based on the weight of the wire (wire core plus coating layer). At the same time, in an embodiment, the total proportion of said at least one member selected from the group consisting of antimony, bismuth, arsenic and tellurium may be in the range of 300 to 3500 wt.-ppm, preferably 300 to 2000 wt.-ppm, based on the weight of the gold of the outer gold layer.

It is preferred that antimony is present within the outer gold layer. It is even more preferred that antimony is alone present within the gold layer, i.e. without the simultaneous presence of bismuth, arsenic and tellurium. In other words, in a preferred embodiment, the gold layer comprises antimony in a proportion in the range of 10 to 300 wt.-ppm, preferably 10 to 120 wt.-ppm, most preferably 20 to 120 wt.-ppm, based on the weight of the wire (wire core plus coating layer), without bismuth, arsenic and tellurium being present within the gold layer; at the same time, in an even more preferred embodiment, the proportion of the antimony may be in the range of 300 to 3500 wt.-ppm, preferably 300 to 2000 wt.-ppm, based on the weight of the gold of the gold layer.

In an embodiment, the at least one member selected from the group consisting of antimony, bismuth, arsenic and tellurium may exhibit a concentration gradient within the gold layer, said gradient increasing in the direction towards the wire core, i.e. in perpendicular direction to the longitudinal axis of the wire core.

It is unknown in what chemical form or as what chemical species said at least one member is present in the gold layer, i.e. whether it is present in the gold layer in elemental form or in the form of a chemical compound.

The 15 to 50 μm thick round coated wire (i.e. the wire having a diameter of 15 to 50 μm, and comprising a silver-based wire core with a surface, the wire core having a coating layer superimposed on its surface, wherein the coating layer is a double-layer comprised of a 1 to 40 nm thick inner layer of palladium or preferably nickel and an adjacent 20 to 500 nm thick outer layer of gold) can be made by a process comprising at least the steps (1) to (5):
(1) providing a silver-based precursor item,
(2) elongating the precursor item to form an elongated precursor item, until an intermediate diameter in the range of from 30 to 200 μm is obtained,
(3) applying a double-layer coating of an inner layer of palladium or preferably nickel and an adjacent outer layer of gold on the surface of the elongated precursor item obtained after completion of process step (2),
(4) further elongating the coated precursor item obtained after completion of process step (3) until a desired final diameter and a double-layer comprised of an inner layer of palladium or preferably nickel having a desired final thickness in the range of 1 to 40 nm and an adjacent outer layer of gold having a desired final thickness in the range of 20 to 500 nm is obtained, and
(5) finally strand annealing the coated precursor obtained after completion of process step (4) at an oven set temperature in the range of from 200 to 600° C. for an exposure time in the range of from 0.4 to 0.8 seconds to form the coated wire,
wherein step (2) may include one or more sub-steps of intermediate batch annealing of the precursor item at an oven set temperature of from 400 to 800° C. for an exposure time in the range of from 50 to 150 minutes, and
wherein the application of the gold layer in step (3) is performed by electroplating it from a gold electroplating bath.

The 15 to 50 μm thick round coated wire in its preferred embodiment can be made by that same process with the proviso that the gold electroplating bath comprises not only gold but also at least one member selected from the group consisting of antimony, bismuth, arsenic and tellurium.

The term “strand annealing” is used herein. It is a continuous process allowing for a fast production of a wire with high reproducibility. In the context of the invention, strand annealing means that the annealing is done dynamically while the coated precursor to be annealed is pulled or moved through a conventional annealing oven and spooled onto a reel after having left the annealing oven. Here, the annealing oven is typically in the form of a cylindrical tube of a given length. With its defined temperature profile at a given annealing speed which may be chosen in the range of, for example, from 10 to 60 meters/minute the annealing time/oven temperature parameters can be defined and set.

The term “oven set temperature” is used herein. It means the temperature fixed in the temperature controller of the annealing oven. The annealing oven may be a chamber furnace type oven (in case of batch annealing) or a tubular annealing oven (in case of strand annealing).

This disclosure distinguishes between precursor item, elongated precursor item, coated precursor item, coated precursor and coated wire. The term “precursor item” is used for those wire pre-stages which have not reached the desired final diameter of the wire core, while the term “precursor” is used for a wire pre-stage at the desired final diameter. After completion of process step (5), i.e. after the final strand annealing of the coated precursor at the desired final diameter a coated wire in the sense of the invention is obtained.

The precursor item as provided in process step (1) is a silver-based precursor item; i.e. the precursor item consists of (a) doped silver, (b) a silver alloy or (c) a doped silver alloy. As regards the meaning of the terms “doped silver”, “silver alloy” and “doped silver alloy” reference is made to the afore made disclosure.

In the embodiment of a silver-based precursor item the latter can be obtained by alloying, doping or alloying and doping silver with the desired amount of the required components. The doped silver or silver alloy or doped silver alloy can be prepared by conventional processes known to the person skilled in the art of metal alloys, for example, by melting together the components in the desired proportional ratio. In doing so, it is possible to make use of one or more conventional master alloys. The melting process can for example be performed making use of an induction furnace and it is expedient to work under vacuum or under an inert gas atmosphere. The materials used can have a purity grade of, for example, 99.99 wt.-% and above. The melt so-produced can be cooled to form a homogeneous piece of silver-based precursor item. Typically, such precursor item is in the form of a rod having a diameter of, for example, 2 to 25 mm and a length of, for example, 2 to 100 m. Such rod can be made by continuous casting the silver-based melt using an appropriate mold, followed by cooling and solidifying.

In process step (2) the precursor item is elongated to form an elongated precursor item, until an intermediate diameter in the range of from 30 to 200 μm is obtained. Techniques to elongate a precursor item are known and appear useful in the context of the invention. Preferred techniques are rolling, swaging, die drawing or the like, of which die drawing is particularly preferred. In the latter case the precursor item is drawn in several process steps until the desired intermediate diameter is reached. Such wire die drawing process is well known to the person skilled in the art. Conventional tungsten carbide and diamond drawing dies may be employed and conventional drawing lubricants may be employed to support the drawing.

Step (2) of the process of the invention may include one or more sub-steps of intermediate batch annealing of the elongated precursor item at an oven set temperature in the range of from 400 to 800° C. for an exposure time in the range of from 50 to 150 minutes. Said optional intermediate batch annealing may be performed, for example, with a rod drawn to a diameter of 2 mm and coiled on a drum.

The optional intermediate batch annealing of process step (2) may be performed under an inert or reducing atmosphere. Numerous types of inert atmospheres as well as reducing atmospheres are known in the art and are used for purging the annealing oven. Of the known inert atmospheres, nitrogen or argon are preferred. Of the known reducing atmospheres, hydrogen is preferred. Another preferred reducing atmosphere is a mixture of hydrogen and nitrogen. Preferred mixtures of hydrogen and nitrogen are 90 to 98 vol.-% nitrogen and, accordingly, 2 to 10 vol.-% hydrogen, wherein the vol.-% total 100 vol.-%. Preferred mixtures of nitrogen/hydrogen are equal to 93/7, 95/5 and 97/3 vol.-%/vol.-%, each based on the total volume of the mixture.

In process step (3) a coating in the form of a double-layer coating of an inner layer of palladium or preferably nickel and an adjacent outer layer of gold is applied on the surface of the elongated precursor item obtained after completion of process step (2) so as to superimpose the coating over said surface.

The skilled person knows how to calculate the thickness of such coating on an elongated precursor item to finally obtain the coating in the layer thickness disclosed for the embodiments of the wire, i.e. after finally elongating the coated precursor item. The skilled person knows numerous techniques for forming a coating layer of a material according to the embodiments on a silver-based surface. Preferred techniques are plating, such as electroplating and electroless plating, deposition of the material from the gas phase such as sputtering, ion plating, vacuum evaporation and physical vapor deposition, and deposition of the material from the melt. It is preferred to apply the inner palladium layer or the preferred inner nickel layer by electroplating.

The gold layer is applied by electroplating. Gold electroplating is performed making use of a gold electroplating bath, i.e. an electroplating bath that allows for a palladium or a nickel cathode surface to be electroplated with gold. In other words, the gold electroplating bath is a composition allowing for direct application of gold in elemental, metallic form onto a palladium or nickel surface wired as cathode. The gold electroplating bath comprises gold. The concentration of the gold in the gold electroplating bath can be in the range of, for example, 8 to 40 g/l (grams per liter), preferably 10 to 20 g/l.

As already mentioned above, the gold electroplating bath may also comprise at least one member selected from the group consisting of antimony, bismuth, arsenic and tellurium; here, the gold electroplating bath is a composition allowing for the deposition of not only the elemental gold but also allowing for depositing said at least one member selected from the group consisting of antimony, bismuth, arsenic and tellurium within the gold layer. It is unknown what chemical species said at least one member is, i.e. whether it is present in the gold layer in elemental form or as a chemical compound. Such gold electroplating bath can be made by adding said at least one member in a suitable chemical form (e.g. compounds like Sb₂O₃, BiPO₄, AS₂O₃ or TeO₂) to an aqueous composition containing gold as dissolved salt or dissolved salts. Examples of such aqueous compositions into which the at least one member can be added are Aurocor® K 24 HF made by Atotech and Auruna® 558 and Auruna® 559 made by Umicore. Alternatively, one can use a gold electroplating bath which already comprises at least one member selected from the group consisting of antimony, bismuth, arsenic and tellurium, like for example MetGold Pure ATF made by Metalor. The concentration of the gold in the gold electroplating bath can be in the range of, for example, 8 to 40 g/l (grams per liter), preferably 10 to 20 g/l. The concentration of the at least one member selected from the group consisting of antimony, bismuth, arsenic and tellurium in the gold electroplating bath can be in the range of, for example, 15 to 1000 wt.-ppm.

Electroplating application of the gold layer is performed by guiding the palladium- or nickel-coated elongated precursor item wired as a cathode through the gold electroplating bath. The so obtained gold-coated precursor item exiting the gold electroplating bath may be rinsed and dried before process step (4) is performed. The use of water as a rinsing medium is expedient, with alcohol and alcohol/water mixtures being further examples of rinsing media. The gold electroplating of the palladium- or nickel-coated elongated precursor item passing through the gold electroplating bath can take place at a direct voltage in the range of, for example, 0.2 to 20 V at a current in the range of, for example, 0.001 to 5 A, in particular 0.001 to 1 A or 0.001 to 0.2 A. Typical contact times may be in the range of, for example, 0.1 to 30 seconds, preferably 2 to 8 seconds. The current densities used in this context can be in the range of, for example, 0.01 to 150 A/dm². The gold electroplating bath may have a temperature in the range of, for example, 45 to 75° C., preferably 55 to 65° C.

The thickness of the gold coating layer can be adjusted as desired essentially via the following parameters: chemical composition of the gold electroplating bath, contact time of the elongated precursor item with the gold electroplating bath, current density. In this context, the thickness of the gold layer can generally be increased by increasing the concentration of the gold in the gold electroplating bath, by increasing the contact time of the elongated precursor item wired as cathode and the gold electroplating bath, and by increasing the current density.

In process step (4) the coated precursor item obtained after completion of process step (3) is further elongated until (4) a desired final cross-section or diameter of the wire having a double-layer comprised of an inner layer of palladium or preferably nickel having a desired final thickness in the range of 1 to 40 nm, preferably 1.5 to 15 nm, and an adjacent outer layer of gold having a desired final thickness in the range of 20 to 500 nm, preferably 30 to 350 nm, is obtained. Techniques to elongate the coated precursor item are the same elongation techniques like those mentioned above in the disclosure of process step (2).

In process step (5) the coated precursor obtained after completion of process step (4) is finally strand annealed at an oven set temperature in the range of from 200 to 600° C., preferably 350 to 500° C. for an exposure time in the range of from 0.4 to 0.8 seconds to form the coated wire. Process step (5) may be performed under atmosphere or purging nitrogen or forming gas.

In a preferred embodiment, the finally strand annealed coated precursor, i.e. the still hot coated wire is quenched in water which, in an embodiment, may contain one or more additives, for example, 0.01 to 0.2 volume-% of additive(s). The quenching in water means immediately or rapidly, i.e. within 0.2 to 0.8 seconds, cooling the finally strand annealed coated precursor from the temperature it experienced in process step (5) down to room temperature, for example by dipping or dripping.

After completion of process step (5) and the optional quenching the coated wire is finished. The coated wire can be ball-bonded to a bond pad of a semiconductor device.

The ball-bond arrangement of the invention can be made by a process comprising the subsequent steps (i) and (ii), as are disclosed in the following. Hence, in an embodiment, the invention relates to a process for the manufacture of a ball-bond arrangement comprising the steps:
(i) providing a semiconductor having a bond pad and a wire according to any of its afore disclosed embodiments, and
(ii) ball-bonding the wire to the bond pad, wherein ball-bonding includes FAB formation at a BSR in the range of 1.5 to 2.2.

In step (i) a semiconductor having a bond pad and a wire according to any of its afore disclosed embodiments are provided. With regard to processes for the manufacture of such a wire reference is made to the disclosure above.

In step (ii) the wire is ball-bonded to the bond pad of the semiconductor device. To this end, first of all, an FAB is prepared at the tip of the wire by performing electric flame-off (EFO) firing in ambient atmosphere (air atmosphere). It is essential to prepare the FAB at a BSR in the range of 1.5 to 2.2, preferably 1.6 to 2.0; hence, it may be worked at an EFO current in the range of, for example, 20 to 120 mA, preferably 40 to 70 mA, most preferred 40 to 50 mA, and at an EFO time in the range of, for example, 75 to 1400 us, preferably 140 to 550 us, most preferred 140 to 350 us, and with a wand gap (distance between EFO electrode tip and fractured wire tip) in the range of, for example, 625 to 1125 μm, preferably 700 to 900 μm. Examples of well-known bonders, to name only a few, include the IConn—KNS bonder, the Shinkawa bonder and the ASM bonder.

As already mentioned above, the ball-bonding procedure as such, i.e. the descending of the formed FAB so as to touch the bond pad of the semiconductor device and to ball-bond the wire, is well-known to the person skilled in the art and comprises no methodological peculiarities. A usual ball-bonding equipment can be used, in particular one of the three well-known bonders as disclosed above. The bonding process parameters may be: bonding force in the range of, for example, 22 to 30 g; ultrasonic energy in the range of, for example, 78 to 94 mA; temperature in the range of, for example, 170 to 250° C.; contact velocity in the range of, for example, 6 to 20 μm/ms.

### WIRE EXAMPLES

98.5 wt.-% of silver (Ag) and 1.5 wt.-% of palladium (Pd), each exhibiting at least 99.99 wt.-% purity (“4N”), were melted in a crucible. Then wire core precursor items in the form of 8 mm rods were continuous cast from the melt. The rods were then drawn in several drawing steps to form wire core precursors having a circular cross-section with a diameter of 2 mm. The wire core precursors were intermediate batch annealed at an oven set temperature of 500° C. for an exposure time of 60 minutes. The rods were further drawn in several drawing steps to form wire core precursors having a circular cross-section with a diameter of 46 μm.

The wire core precursors were electroplated with an outer layer of gold, according to Table 1.

In wire examples 1 and 2, the gold layer was directly electroplated onto the wire core precursors without precoating an inner palladium or nickel layer. In wire examples with antimony being present in the gold layer, the wire core precursors while being wired as cathode were moved through a 61° C. warm gold electroplating bath (based on MetGold Pure ATF from Metalor) having a gold content of 14.5 g/l; the antimony content of the various electroplating bath employed was in each case in the range of 20 to 100 wt.-ppm.

In wire examples with an inner nickel layer, the wire core precursors were electroplated with a double-layer coating of an inner layer of nickel and an adjacent outer layer of gold. To this end, the wire core precursors while being wired as cathode were moved through a 60° C. warm nickel electroplating bath (comprising 90 g/l (grams per liter) Ni (SO₃NH₂)₂, 6 g/l NiCl₂ and 35 g/l H₃BO₃) and, subsequently, through a 61° C. warm gold electroplating bath.

All coated wire precursors were further drawn to a final diameter of 20 μm, followed by a final strand annealing at an oven set temperature of 430° C. for an exposure time of 0.6 seconds, immediately followed by quenching the so-obtained coated wires in an aqueous quenching solution (deionized water containing 0.07 vol.-% of surfactant). The contact time of each wire with the aqueous quenching solution was 0.3 s.

Wire samples of all wires were bonded using an IConn—KNS bonder with the respective bonding parameters specified in Table 1 under ambient air atmosphere (T=20° C. and a relative humidity RH=50%). The FABs were descended to Al-0.5 wt.-% Cu bond pads of 16 pSOP devices (plastic small outline package devices, i.e. surface mount integrated circuit packages well-known in the semiconductor sector) from a predefined height (tip of 203.2 μm) with a contact velocity of 6.4 μm/ms). Upon touching the bond pad, a set of defined bonding parameters (bond force of 30 g, ultrasonic energy of 90 mA and bond time of 15 ms) took into effect to deform the FABs and form bonded balls. After forming the bonded balls, the capillary rose to a predefined height (kink height of 152.4 μm and loop height of 254 μm) to form a loop. After forming the loop, the capillary descended to a lead to form a stitch. After forming the stitch, the capillary rose and the wire clamp closed to cut the wires to make a predefined tail length (tail length extension of 254 μm).

### Test Methods

All tests and measurements were conducted at T=20° C. and a relative humidity RH=50%.

A. Biased Highly Accelerated Stress Test (bHAST) of Ball-Bond Arrangements:

Each wire sample was ball-bonded to ten 16 pSOP devices being attached on a strip. Each strip was epoxy molded and tested for reliability by performing a standard highly accelerated stress test at 130° C., 85% RH, and biased at +20V in a HAST chamber. The 16 bonded balls of each of the ten 16 pSOP devices were daisy-chained and the development of the electrical resistance was monitored. A ≥10% increase of electrical resistance within 480 hours or earlier indicated a device failure due to ball-bond interconnect failure. The wire sample was indicated as having passed the test when the electrical resistance remained constant over the entire test duration of 480 hours.

Further, all bonded balls were investigated under an optical microscope at 1000 times magnification, to inspect for any potential lifted bonded balls. To this end, tested 16 pSOP devices were carefully decapsulated and examined for lifted bonded balls, i.e. for mechanical integrity with the bond pads. Any lifted bonded balls were indicative of interfacial galvanic corrosion failure type.

### B. SEM EDX Analysis of Cross-Sectioned Ball-Bond Arrangements:

The ball-bond arrangement was epoxy potted, mechanically cross-sectioned to center of the ball-bond, and then ion-milled to attain scratch-free cross-sectional view. The ion-milled cross section was observed in SEM; with the support of energy dispersive X-ray attachment to SEM the ion-milled section was dot mapped for gold. It was worked with a magnification of 1300×; an electron beam excitation voltage of 10 kV at a constant electrical current of 250 pA, for 60 μm aperture, 10 mm working distance. The dot mapping for gold was performed by looking for a spread of gold dots along the entire periphery of the bonded ball from its neck over its left-hand side, its right-hand side and its bottom. To this end, X-ray counts of elemental gold were picked and represented in a pictorial image as gold dots; accumulations of gold dots of the observed cross-sectioned regions defined presences of elemental gold, while black areas indicated absences of gold. The evaluation of the percentage of the gold coverage was as follows:
− Poor: <70% of the bonded ball's periphery is covered by gold;
+ Good: 70 to 100% of the bonded ball's periphery is covered by gold.

TABLE 1
Overview on comparative examples 1 to 5 and examples according to the invention 6 to 10

| | | Sb in | | | | | | | | |
|---|---|---|---|---|---|---|---|---|---|---|
| | | gold | | | | | | | | |
| | | layer | | | | | | | | |
| | | (wt.- | | | | | | | | |
| | | ppm; | | | | | | | | |
| | | based | | | | | | Gold | Ball | |
| | | on the | | | | | | coverage | bond lift- | |
| | Gold layer | weight | Ni layer | | EFO | | | of | offs | |
| | thickness | of the | thickness | | current | EFO | Wand | bonded | after | Result of |
| Ex. | (nm) | wire) | (nm) | BSR | (mA) | time (μs) | gap (μm) | ball | bHAST | bHAST |
| 1 | 70 | <2 | 0 | 2.0 | 50 | 255 | 750 | − | 11 | Fail |
| 2 | 70 | 50 | 0 | 2.0 | 50 | 255 | 750 | − | 10 | Fail |
| 3 | 70 | 50 | 3 | 2.5 | 50 | 370 | 750 | − | 9 | Fail |
| 4 | 70 | 50 | 3 | 2.3 | 100 | 160 | 750 | − | 8 | Fail |
| 5 | 18 | 50 | 3 | 2.0 | 50 | 255 | 750 | − | 8 | Fail |
| 6 | 70 | 50 | 3 | 2.0 | 50 | 255 | 750 | + | 0 | Pass |
| 7 | 200 | 50 | 3 | 2.0 | 50 | 255 | 750 | + | 0 | Pass |
| 8 | 70 | 120 | 3 | 2.0 | 50 | 255 | 750 | + | 0 | Pass |
| 9 | 70 | 50 | 3 | 1.8 | 50 | 205 | 750 | + | 0 | Pass |
| 10 | 70 | 50 | 3 | 1.5 | 45 | 140 | 750 | + | 0 | Pass |

1. A ball-bond arrangement comprising a bond pad of a semiconductor device and a wire ball-bonded to the bond pad,
wherein the wire extending from the bonded ball has a diameter of 15 to 50 μm, and comprises a silver-based wire core with a surface, the wire core having a coating layer superimposed on its surface,
wherein the coating layer is a double-layer comprised of a 1 to 40 nm thick inner layer of palladium or nickel and an adjacent 20 to 500 nm thick outer layer of gold, and
wherein the surface of the bonded ball has a gold coverage of 70 to 100%.

2. The ball-bond arrangement of claim 1, wherein the outer gold layer comprises at least one member selected from the group consisting of antimony, bismuth, arsenic and tellurium in a total proportion in the range of from 10 to 300 wt.-ppm, based on the weight of the wire.

3. The ball-bond arrangement of claim 2, wherein the total proportion of the at least one member selected from the group consisting of antimony, bismuth, arsenic and tellurium is in the range of 300 to 3500 wt.-ppm, based on the weight of the gold of the outer gold layer.

4. The ball-bond arrangement of claim 1, wherein the silver-based material of the wire core is doped silver, a silver alloy or a doped silver alloy.

5. The ball-bond arrangement of claim 4, wherein the silver alloy comprises palladium as the only alloying element.

6. The ball-bond arrangement of claim 1, wherein antimony is present within the outer gold layer.

7. The ball-bond arrangement of claim 1, wherein the bond pad consists of a metal M, of an alloy of >90 wt.-% of a metal M, or of a metal other than the metal M with an outer metal M (alloy) top layer, wherein the metal M is aluminum, gold, silver, copper, palladium or nickel.

8. A process for the manufacture of the ball-bond arrangement of claim 1 comprising the subsequent steps:
(i) providing a semiconductor having a bond pad and a wire having a diameter of 15 to 50 μm, and comprising a silver-based wire core with a surface, the wire core having a coating layer superimposed on its surface,
wherein the coating layer is a double-layer comprised of a 1 to 40 nm thick inner layer of palladium or nickel and an adjacent 20 to 500 nm thick outer layer of gold, and
(ii) ball-bonding the wire to the bond pad, wherein ball-bonding includes FAB formation at a BSR in the range of 1.5 to 2.2.

9. The process of claim 8, wherein the outer gold layer comprises at least one member selected from the group consisting of antimony, bismuth, arsenic and tellurium in a total proportion in the range of from 10 to 300 wt.-ppm, based on the weight of the wire.

10. The process of claim 9, wherein the total proportion of the at least one member selected from the group consisting of antimony, bismuth, arsenic and tellurium is in the range of 300 to 3500 wt.-ppm, based on the weight of the gold of the outer gold layer.

11. The process of claim 8, wherein the silver-based material of the wire core is doped silver, a silver alloy or a doped silver alloy.

12. The process of claim 11, wherein the silver alloy comprises palladium as the only alloying element.

13. The process of claim 8, wherein antimony is present within the outer gold layer.

14. The process of claim 8, wherein the bond pad consists of a metal M, of an alloy of >90 wt.-% of a metal M, or of a metal other than the metal M with an outer metal M (alloy) top layer, wherein the metal M is aluminum, gold, silver, copper, palladium or nickel.
